(19) United States
(12) Patent Application Publication
(10) Pub. No.: US 2022/0139845 A1
(43) Pub. Date: May 5, 2022

(54) SEMICONDUCTOR PACKAGE WITH ELECTROMAGNETIC SHIELD

(71) Applicant: STMICROELECTRONICS, INC., Calamba City (PH)

(72) Inventors: Endalicio MANALO, Batangas (PH); Rennier RODRIGUEZ, Bulacan (PH)

(73) Assignee: STMICROELECTRONICS, INC., Calamba City (PH)

(21) Appl. No.: 17/509,758

(22) Filed: Oct. 25, 2021

Related U.S. Application Data
(60) Provisional application No. 63/108,081, filed on Oct. 30, 2020.

(51) Int. Cl. H01L 23/552; H01L 23/495; H01L 23/29; H01L 23/31

(52) U.S. Cl. CPC H01L 23/552; H01L 23/31; H01L 23/293; H01L 23/49541

(57) ABSTRACT

The present disclosure is directed to a semiconductor package that include a non-conductive encapsulation layer encapsulation an integrated circuit chip, and a conductive encapsulation layer over the non-conductive encapsulation layer. A lead is exposed from the non-conductive encapsulation layer and contacts the conductive encapsulation layer. The conductive encapsulation layer and the lead provide EMI shielding for the integrated circuit chip.

### BACKGROUND

### Technical Field

Embodiments of the present disclosure are directed to semiconductor packages and assembling technology.

### Description of the Related Art

Semiconductor packages are becoming increasingly thinner and smaller, and at the same time, more sensitive electrical components and connection features are being added to these semiconductor packages. The increased density of electrical components brings about significant challenges to avoid or reduce exposure to electromagnetic interference (EMI) for a semiconductor die, electrical connections, and other electrical components integrated within a semiconductor package.

Leadless (or no lead) packages are often utilized in applications with smaller sized packages. Typically, the flat leadless packages provide a near chip scale encapsulated package formed from a planar leadframe. Lands located on a lower surface of the package provide electrical connection to another device, such as a printed circuit board (PCB). Leadless packages, such as quad flat no-lead (QFN) packages, include a semiconductor die or chip mounted to a support surface of a leadframe, such as a die pad or ends of leads. The semiconductor die is electrically coupled to the leads, often by conductive wires.

### BRIEF SUMMARY

Generally described, one or more embodiments are directed to semiconductor packages with EMI shields provided by an outer conductive encapsulation layer. A non-conductive encapsulation layer is under the conductive encapsulation layer and separates electrical components in the package from the conductive encapsulation layer. More specifically, the non-conductive material encases the electrical components of the package, such as a die, contact pads, electrical connections, wires, and the like, and the conductive material covers the non-conductive material to protect the electrical components of the package from EMI. The conductive material is grounded to short any EMI charge to ground without it reaching the electrical components. Specifically, in some embodiments, the semiconductor package is a QFN package that includes a plurality of leads.

The plurality of leads includes connection leads that are electrically coupled to bonding pads of a semiconductor die and thereby coupled to active components of the semiconductor die. The plurality of leads also includes one or more grounding leads. The grounding leads are exposed from a sidewall of the non-conductive encapsulation layer and contacts the conductive encapsulation layer to ground the conductive layer. The connection leads are not exposed from the sidewall of the non-conductive material and are insulated from the conductive material by the non-conductive material.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale.

FIG. 1A is a cross-sectional view of a semiconductor package according to embodiments of the disclosure.

FIG. 1B is a bottom view of the semiconductor package of FIG. 1A.

FIG. 2 is a cross-sectional view of a semiconductor package according to embodiments of the disclosure.

FIG. 3 is a cross-sectional view of a semiconductor package according to embodiments of the disclosure.

FIGS. 4-6 are cross-sectional views of various stages of a packaging process according to embodiments of the disclosure.

### DETAILED DESCRIPTION

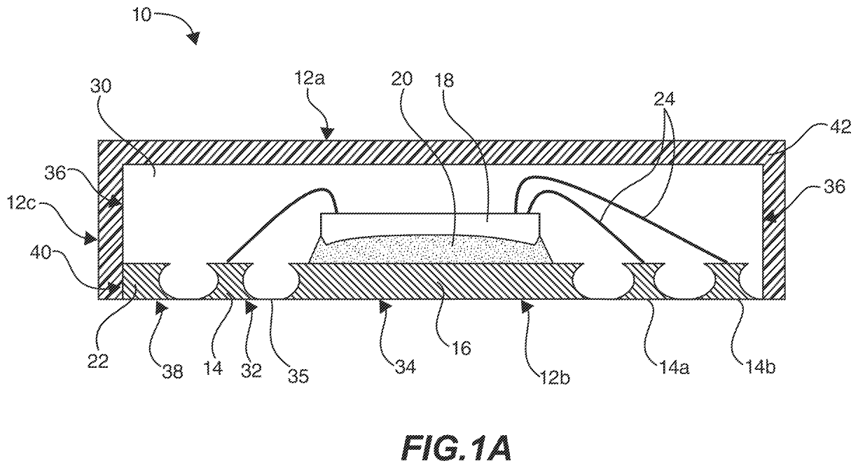

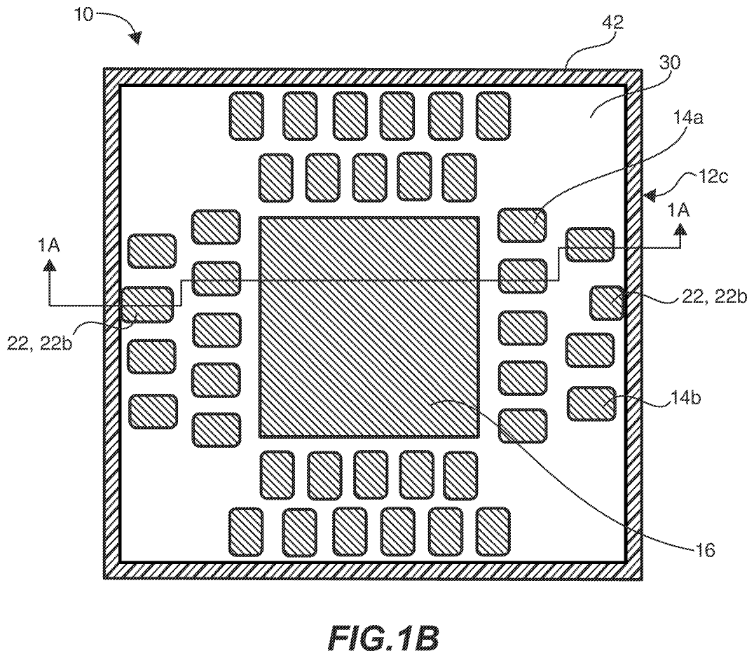

FIG. 1A shows a cross-sectional view of a QFN semiconductor package 10 of a semiconductor device through line 1A-1A of FIG. 1B. FIG. 1B shows a bottom view of the QFN semiconductor package 10.

The semiconductor package 10 includes an upper surface 12a, a lower surface 12b, and side surfaces 12c. The semiconductor package 10 includes a plurality of connection leads 14 and a die pad or a thermal pad 16. The connection leads 14 may include an inner group 14a and an outer group 14b. The connections leads 14 in the outer group 14b are proximal to the side surface 12c, while the connection leads 14 in the inner group 14a are portioned between the outer group 14b and the die pad 16. FIGS. 1A and 1B show one ring of connection leads 14 in the inner group 14a for illustration, which does not limit the scope of the disclosure. For example, a package may include multiple rings of connection leads 14 in the inner group 14a.

A semiconductor die or chip 18 is positioned at least over the die pad 16. In some embodiments, the die 18 may also be positioned over one or more rings of connection leads 14 in the inner group 14a. The plurality of leads 14 may be symmetrically arranged about one or more axes and may be symmetrically arranged about an axis of the semiconductor die 18. In some embodiments, die attachment material 20, e.g., conductive adhesive material or die attachment film, may be positioned between the die 18 and the die pad 16. In some embodiments, the package does not include a continuous die pad, and includes a plurality of discrete leads or lead-like column structures that together function as a “die pad” to support or hold the die 18.

The package 10 also includes one or more grounding leads 22. The grounding leads 22 extend closer to a respective proximal side surface 12c of the package 10 than a connection lead 14. In some embodiments, a grounding lead 22 is arranged roughly in line with or among the connection leads 14 in the outer group 14b, and extends closer to the respective proximal side surface 12c than the nearby connection lead 14 in the outer group 14b with respect to the same side surfaces 12c of the semiconductor package 10. It should be appreciated that the package 10 may also include leads that do not function for electrical connections/couplings as the connection leads 14 or as the grounding lead 22 and may be structured to function as structural/physical elements only, e.g., the leads that supports the die 18.

The semiconductor die 18, e.g., an integrated circuit die, is made from semiconductor material, such as silicon, and includes an active surface integrating one or more electrical components (not specifically shown for simplicity), such as integrated circuits. The active surface of the semiconductor die 18 includes connection features, e.g., conductive bond pads, which are electrically connected to one or more of the electrical components.

The active surface of the semiconductor die 18 is electrically coupled to the connection leads 14. For example, the bond pads (not specifically shown for simplicity) of the semiconductor die 18 are electrically coupled to surfaces of the connection leads 14 by conductive wires 24, respectively. For example, a first end of a conductive wire 24 is coupled to a bond pad of the semiconductor die 18, and a second end of the conductive wire 24 is coupled to a first surface of the connection lead 14.

In some embodiments, as shown in FIG. 1A as an example, a grounding lead 22 is not electrically coupled to the semiconductor die 18. The electrical components of the die 18 may be grounded through the pad 16 or other grounding terminals. In some embodiments, a grounding lead 22 is electrically coupled to the die 18 to provide a ground terminal for at least some electrical components of the die 18.

The package 10 includes a non-conductive encapsulation layer 30 that encapsulates or covers the die 18, the conductive wires 24, and the connection leads 14, except for the lower surface 12b of the package 10. That is, each connection lead 14 includes a lower or exterior surface 32 and the die pad 16 includes a lower, exterior surface 34 exposed from the non-conductive encapsulation layer 30. The exposed lower surfaces 32, 34 function to contact to a substrate (not specifically shown for simplicity) that carries or holds the package 10, and are referred to as “landing surfaces” or contact pads for descriptive purposes. The connection leads 14 in the outer group 14b are encapsulated within a sidewall 36 of the non-conductive encapsulation layer 30. In some embodiments, each connection lead 14 includes curved sidewalls 15 formed from an etching or leadframe removal process. Other shapes or profiles of the connection leads 14 are also possible and included in the scope of the disclosure. The connection lead 14b is spaced from a conductive encapsulation layer 42 by a portion 37 of the non-conductive encapsulation layer 30. That is, the connection lead 14b is encapsulated within the sidewall 36 of the non-conductive encapsulation layer 30.

The non-conductive encapsulation layer 30 includes a lower surface 35 at the lower surface 12b of the package 10. In some embodiments, the lower surface 35 of the non-conductive encapsulation layer 30 is substantially at a same level as, e.g., coplanar with, the landing surfaces 32, 34 of the connection leads 14, die pad 16, respectively. In some embodiments, the landing surfaces 32 of the connection leads 14 extend or protrude out beyond the lower surface 35 of the non-conductive encapsulation layer 30.

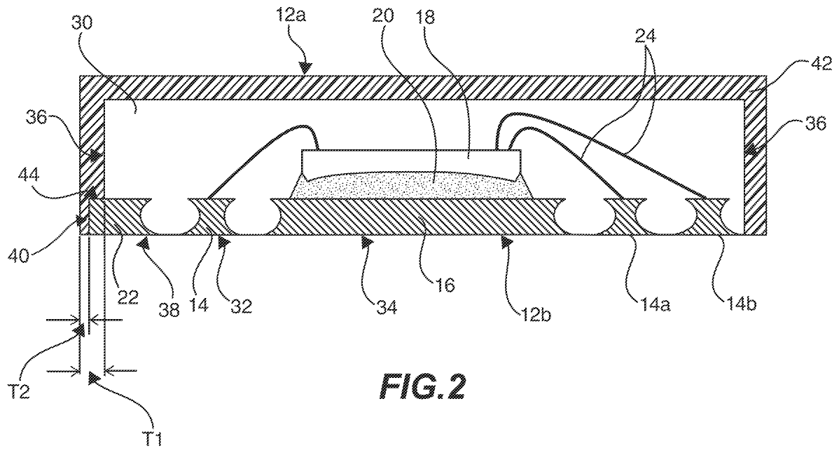

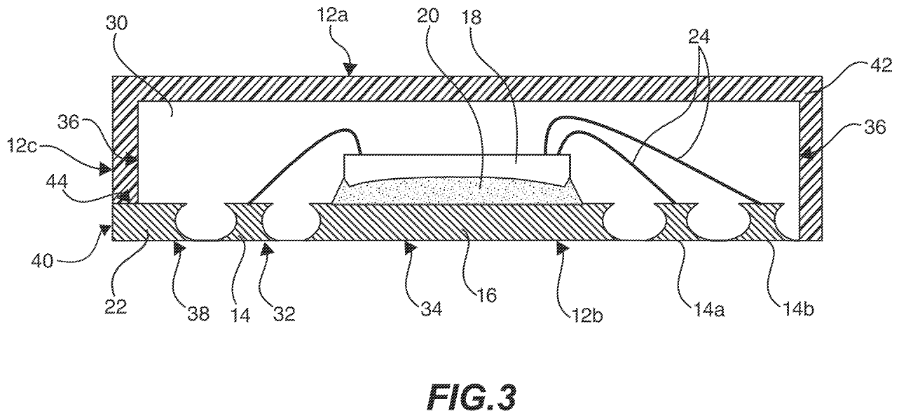

The grounding lead 22 includes a landing surface 38 on the lower surface 12b of the package 10 and a side surface 40 that is exposed from a sidewall 36 of the non-conductive encapsulation layer 30. In some embodiments, as shown in FIG. 1A as an example, side surface 40 of the grounding lead 22 substantially aligns with, e.g., is plumb or coplanar with, sidewall 36 of the non-conductive encapsulation layer 30. In some embodiments, as shown in FIGS. 2 and 3, as examples, the side surface 40 of the grounding lead 22 extends or protrudes out beyond the sidewall surface 36 of the non-conductive encapsulation layer 30.

In some embodiments, the lower surface 35 of the non-conductive encapsulation layer 30 is substantially at a same level as, e.g., coplanar with, the landing surface 38 of the grounding lead 22. In some embodiments, the landing surface 38 of the grounding lead 22 extends or protrudes out beyond the lower surface 35 of the non-conductive encapsulation layer 30. In some embodiments, the landing surface 38 of the grounding lead 22 is substantially at a same level, e.g., planar with, the landing surface 32 of the connection lead 14.

In some embodiment, the non-conductive encapsulation layer is epoxy molding compound or other suitable non-conductive materials.

Referring back to FIGS. 1A and 1B, the package 10 also includes a conductive encapsulation layer 42 over the non-conductive encapsulation layer 30. In some embodiments, the conductive encapsulation layer 42 covers all surfaces of the non-conductive encapsulation layer 30 except for the lower surface 35 thereof at the lower surface 12b of the package 10. The conductive encapsulation layer 42 contacts one or more of the side surfaces 40 of the grounding lead 22 or a portion (FIGS. 2 and 3) of an upper surface 44 of the grounding lead 22 that is exposed from the non-conductive encapsulation layer 30. As shown in FIG. 2, the conductive encapsulation layer 42 includes a thickness T1 on the sidewalls 36 of the non-conductive encapsulation layer 30 and a thickness T2 on the side surface 40 of the grounding lead 22. In one embodiment, as shown in FIG. 2, the thickness T1 is greater than the thickness T2 as the sidewall 40 of the grounding lead 22 protrude beyond the sidewall 36 of the non-conductive encapsulation layer 30. In some other embodiments, as shown in FIG. 1A, these thickness T1 and T2 are substantially the same.

FIG. 1A shows, as an embodiment, that the lower surface 43 of the conductive encapsulation layer 42 is substantially coplanar with the landing surfaces 32, 34, 38 of the die pad 16, connection lead 14 and the grounding lead 22 at the lower surface 12b of the package 10. In some other embodiments, the lower surface 43 may terminate before reaching the lower surface 12b or may extend downwardly beyond the lower surface 12b.

The wires 24 are coupled between the die 18 and ones of the leads 14. This provides an electrical connection from external to the package, through the landing surface 32 of the connection lead 14, the wires 24, and to the die 18.

In some embodiments, the wires 24 are also coupled to one or more of the grounding leads 22 so that at least some electrical components in the die 18 are grounded through the grounding lead 22, via wires 24. In some embodiments, a grounding lead 22 that is coupled to wires 24 may have a larger surface area than a grounding lead 22 that is not coupled to wires 24. FIG. 1B shows that grounding lead 22a has a larger surface area than grounding lead 22b. The larger surface area of the grounding lead 22a facilitates the coupling to the wires 24.

FIGS. 1A, 2, and 3 are embodiments of packages having a conductive encapsulation layer. In FIG. 1A, the conductive encapsulation layer 42 contacts the side surface 40 of the grounding lead 22. In FIG. 2, the conductive encapsulation layer 42 contacts the side surface 40 and a portion of the upper surface 44 of the grounding lead 22. A package 10 may include one or more of the embodiments of FIGS. 1A, 2 and 3 with respect to the structural relationships among the grounding lead 22, the non-conductive encapsulation layer 30, and the conductive encapsulation layer 42, which are all included in the scope of the disclosure. In FIG. 3, the conductive encapsulation layer 30 contacts the upper surface 44 of the grounding lead 22, not the side surface 40, and the side surface 40 is exposed from the conductive encapsulation layer 42. The side surface 40 meets or otherwise extends to the landing surface 38 of the grounding lead 22, and the upper surface 44 is opposite to the landing surface 38. The side surface 40 is coplanar with the surface 12c. In some embodiments, the side surface 40 protrudes beyond the surface 12c such that a portion of the upper surface 44 is exposed from the conductive encapsulation layer 42.

The connection lead 14 is separated or insulated from the conductive encapsulation layer by a portion 37 of the non-conductive encapsulation layer 30.

In some embodiments, the conductive encapsulation layer 42 may be an aluminum layer, a copper layer, a nickel-palladium layer, a silver layer, a gold layer, or some other electrically conductive materials. In some embodiments, the conductive encapsulation layer 42 layer may be a conductive molding compound that includes elements or ions of conductive materials like aluminum, copper, silver, nickel-palladium, gold or other metal materials. The conductive encapsulation layer 42 may also be a conductive compound material like metal nitride, e.g., TiN, TaN, or other suitable conductive compounds.

In some embodiments, the conductive molding compound of the conductive encapsulation layer 42 includes resins and conductive fillers. The fillers each may be a solid body of a conductive material or a filler body coated with an outer layer of a conductive material to produce electrical continuity in the conductive encapsulation layer 42. The resins are binding agents of the molding compound that, e.g., bond the conductive fillers and bond to the non-conductive encapsulation layer 30.

In some embodiments, the conductive encapsulation layer 42 is a semi-sintering glue that includes polymers and conductive fillers. The conductive fillers may include silver, copper, aluminum, gold or other conductive materials. The conductive fillers may each be a solid body of a conductive material or a filler body coated with an outer layer of a conductive material. In some embodiments, the semi-sintering glue also includes a solvent functioning as a triggering agent for curing the polymer and the conductive fillers.

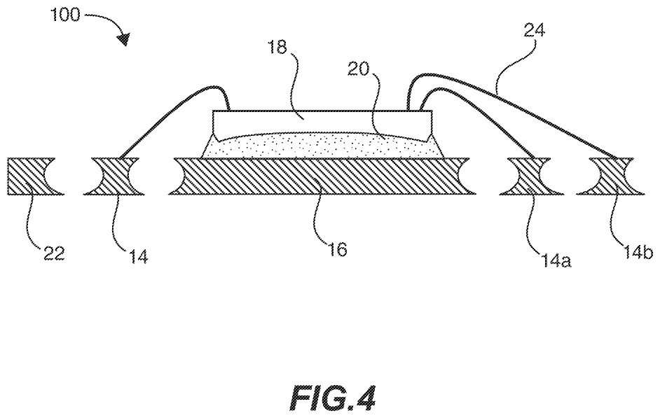

FIGS. 4-6 show an assembly process to form a package 100. In FIG. 4, the die 18 is attached to the die pad 16 with die attachment film 20 applied between the die 18 and the die pad 16. The wire bonding process is conducted to form wires 24 that couple connection terminals (not specifically shown for simplicity) of the die 18 to the connection leads 14 and/or the grounding lead 22.

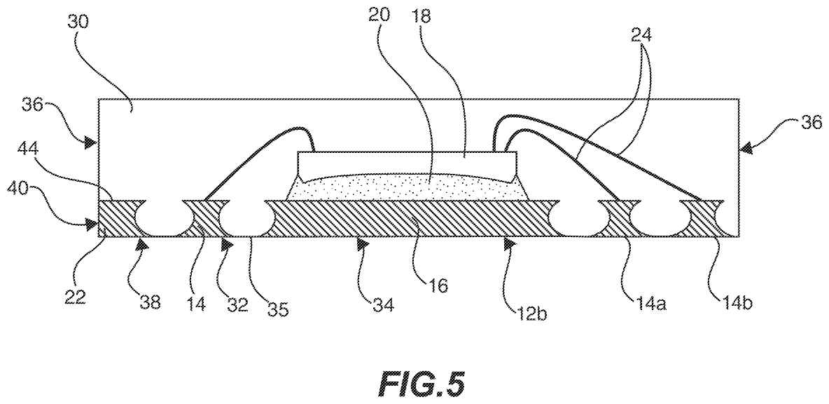

In FIG. 5, non-conductive encapsulation layer 30 is formed covering the die 18, the wires 24, the die pad 16 and the connection leads 14, except for surfaces 32, 34, 35 thereof at the lower surface 12b of the package 10. The lower surfaces 32, 34, 38 of the connection lead 14, the die pad 16 and the grounding lead 22, respectively, are exposed from the non-conductive encapsulation layer 30. The side surface 40, and in some embodiments a portion of the upper surface 44 of the grounding lead 22, are exposed from the non-conductive encapsulation layer 30, or specifically, the sidewall 36 of the no-conductive encapsulation layer 30. The connection leads 14 are encapsulated within the sidewall 36 of the non-conductive encapsulation layer 30.

In some embodiments, the non-conductive encapsulation layer 30 is formed using a printing process. A stencil lay-out may be used to define the borders or dimensions of the non-conductive encapsulation layer 30 formed over the work piece 100. For example, a stencil lay-out may be positioned surrounding each of a plurality of work pieces 100 to define the boarders or dimensions of the non-conductive encapsulation layer 30 formed over each of the plurality of work pieces 100. Other approaches to form the non-conductive encapsulation layer 30 are also possible and included in the scope of the disclosure.

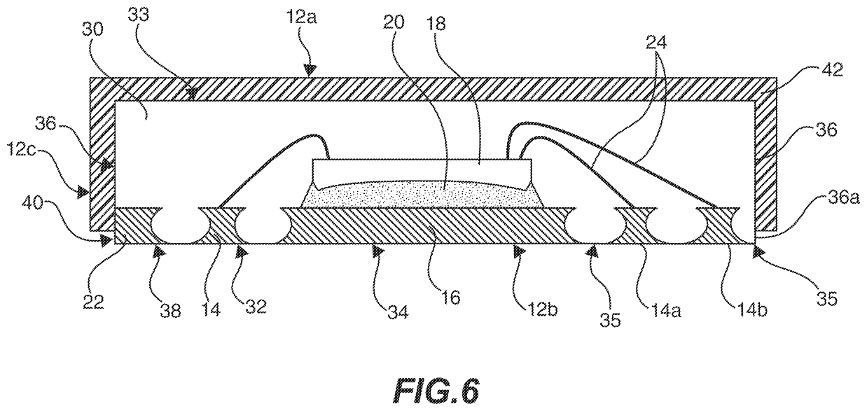

In FIG. 6, the conductive encapsulation layer 42 is formed over the non-conductive encapsulation layer 30. In some embodiments, the conductive encapsulation layer 42 covers the upper surface 33 and the sidewall surfaces 36 of the non-conductive encapsulation layer 30 and leaves the surfaces 32, 34, 35, 38 on the lower surface 12b of the package 10 uncovered from the conductive encapsulation layer 42. As such, the upper surface of the conductive encapsulation layer 42 becomes the upper surface 12a of the package 10, and the sidewall surface of the conductive encapsulation layer 42 becomes sidewall surface 12c of the package 10. In some embodiments, the conductive encapsulation layer 42 on sidewall 36 of the non-conductive encapsulation layer 30 extends to substantially at a same level as the lower surface 35 of the nonconductive encapsulation layer 30. In some embodiments, the conductive encapsulation layer 42 on sidewall 36 of the non-conductive encapsulation layer 30 does not reach the lower surface 35 such that a portion 36a of the sidewall 36 of the non-conductive encapsulation layer 30 is exposed from the conductive encapsulation layer 42. The portion 36a is proximal to the lower surface 35 of the non-conductive encapsulation layer 30.

The conductive encapsulation layer 42 contacts portions of the grounding lead 22 that is exposed from the sidewall 36 of the non-conductive encapsulation layer 30.

The conductive encapsulation layer 42 is may be sputtered onto the outside of the non-conductive encapsulation layer 30. Alternatively or additionally, the conductive material 42 may be spray coated or plated onto the first prior art package 30.

In some embodiments, in the case that the conductive encapsulation layer 42 is a conductive molding compound or a semi-sintering glue, the conductive encapsulation layer 42 is printed over the non-conductive encapsulation layer 30, e.g., using a stencil lay-out to define a border or dimension of the conductive encapsulation layer 42.

Generally described, one or more embodiments are directed to semiconductor packages with EMI shields provided by an outer conductive encapsulation layer. A non-conductive encapsulation layer is under the conductive encapsulation layer and separates electrical components in the package from the conductive encapsulation layer. More specifically, the non-conductive material encases the electrical components of the package, such as a die, contact pads, electrical connections, wires, and the like, and the conductive material covers the non-conductive material to protect the electrical components of the package from EMI. The conductive material is grounded to short any EMI charge to a ground without it reaching the electrical components. Specifically, in some embodiments, the semiconductor package is a QFN package that includes a plurality of leads. The plurality of leads includes connection leads that are electrically coupled to bonding pads of a semiconductor die and thereby coupled to active components of the semiconductor die. The plurality of leads also includes one or more grounding leads. The grounding leads are exposed from a sidewall of the non-conductive encapsulation layer and contact the conductive encapsulation layer to ground the conductive layer. The connection leads are not exposed from the sidewall of the non-conductive material and are insulated from the conductive material by the non-conductive material.

The connection leads and the grounding leads have surfaces that are exposed at a lower surface of the semiconductor package and form lands, which are referred to as “landing surfaces” for descriptive purposes. The landing surfaces of the connection leads and the grounding leads may be coupled to respective connection features of a substrate that holds the QFN package, e.g., a printed circuit board “PCB” or a carrier substrate. For example, the landing surfaces of the grounding leads may be coupled to or contact grounding terminals on the PCB.

The disclosure herein provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the description herein, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

The various embodiments described above can be combined to provide further embodiments. Aspects of the embodiments can be modified to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor package, comprising:
a plurality of leads including a connection lead and a grounding lead;
a semiconductor die;
a first encapsulation layer on the semiconductor die, the conductive wire, and the plurality of leads, the grounding lead being exposed from the sidewall of the first encapsulation layer; and
a second encapsulation layer over the first encapsulation layer, the connection lead being separated from the second encapsulation layer by the first encapsulation layer, the grounding lead in contact with the second encapsulation layer.

2. The semiconductor package of claim 1, wherein the first encapsulation layer is non-conductive and the second encapsulation layer is conductive.

3. The semiconductor package of claim 1, wherein the second encapsulation layer includes a resin and conductive fillers in the resin.

4. The semiconductor package of claim 3, wherein the conductive fillers each includes a filler body and a conductive outer coating on the filler body.

5. The semiconductor package of claim 1, wherein the second encapsulation layer includes a polymer and conductive fillers in the polymer.

6. The semiconductor package of claim 1, wherein the connection lead and the grounding lead each includes a landing surface that is exposed from the first encapsulation layer and the second encapsulation layer.

7. The semiconductor package of claim 6, wherein the second encapsulation layer contacts a side surface of the grounding lead, the side surface meeting the landing surface of the grounding lead.

8. The semiconductor package of claim 7, wherein the side surface of the grounding lead is exposed from a sidewall surface of the first encapsulation layer.

9. The semiconductor package of claim 7, wherein the side surface of the grounding lead is substantially plumb with the sidewall surface of the first encapsulation layer.

10. The semiconductor package of claim 6, wherein the second encapsulation layer contacts a first surface of the grounding lead, the first surface opposite to the landing surface of the grounding lead.

11. A device, comprising:
an integrated circuit chip;
a plurality of leads including a first lead and a second lead;
a first encapsulation layer on the integrated circuit chip, the first lead, and the second lead, only a first surface of the first lead being exposed from the first encapsulation layer, the first surface of the first lead facing a first direction, a first surface of the second lead being exposed from the first encapsulation layer, the first surface of the second lead facing a second direction that is different from the first direction; and
a second encapsulation layer over the first encapsulation layer, the first lead being separated from the second encapsulation layer by the first encapsulation layer, the first surface of the second lead in contact with the second encapsulation layer.

12. The device of claim 11, wherein the first encapsulation layer is non-conductive and the second encapsulation layer is conductive.

13. The device of claim 11, wherein the first surface of the first lead is exposed from the second encapsulation layer, and the second lead includes a second surface that is exposed from the second encapsulation layer and faces the first direction, the second surface of the second lead being substantially coplanar with the first surface of the first lead.

14. The device of claim 11, wherein the first encapsulation layer includes a first surface that faces the first direction and a second surface that meets the first surface, the first surface of the second lead being exposed from the second surface of the first encapsulation layer.

15. The device of claim 14, wherein a first portion of the second surface of the first encapsulation layer is exposed from the second encapsulation layer, the first portion proximal to the first surface of the first encapsulation layer.

16. The device of claim 14, wherein the first surface of the first encapsulation layer is substantially at a same level as the first surface of the first lead.

17. The device of claim 14, wherein the first surface of the first lead protrudes beyond the first surface of the first encapsulation layer.

18. The device of claim 11, wherein the second encapsulation layer includes a plurality of conductive fillers in one of a resin or a polymer.

19. A method, comprising:
forming a non-conductive encapsulation layer on a die, a first lead coupled to the die, and a second lead, the first lead being encapsulated with a sidewall of the non-conductive encapsulation layer, and the second lead being exposed from the sidewall of the non-conductive encapsulation layer; and
forming a conductive encapsulation layer over the non-conductive encapsulation layer, the first lead being separated from the conductive encapsulation layer by the non-conductive encapsulation layer, and the second lead contacting the conductive encapsulation layer.

20. The method of claim 19, wherein the forming the non-conductive encapsulation layer includes printing a non-conductive material over the die, the first lead, and the second lead with a stencil lay-out positioned surrounding the die, the first lead, and the second lead.
